(19) United States
(12) Patent Application Publication
(10) Pub. No.: US 2012/0100688 A1
(43) Pub. Date: Apr. 26, 2012

(54) Self-Aligned Electrode Phase Change Memory

(76) Inventors: DerChang Kau, Cupertino, CA (US); Greg Atwood, Los Gatos, CA (US)

(21) Appl. No.: 13/343,936

(22) Filed: Jan. 5, 2012

Related U.S. Application Data
(62) Division of application No. 12/012,231, filed on Jan. 31, 2008.

(51) Int. Cl. H01L 21/8239

(52) U.S. Cl. 438/382; 257/E21.645; 257/E21.004

(57) ABSTRACT

A phase change memory may be formed with an upper electrode self-aligned to a phase change memory element. In some embodiments, patterning techniques may be used to form the elements of the memory. The memory element may be formed as a sidewall spacer formed on both opposed sides of an elongate strip of material. The resulting elongate strip of phase change memory element material may then be singulated in the same etching step that forms the upper electrodes extending in the column direction. Thus, the memory elements may be singulated in the row direction, while, at the same time, the top electrodes are defined to extend continuously in the column direction.

### CROSS-REFERENCE TO RELATED APPLICATIONS

This application is a divisional of U.S. patent application Ser. No. 12/012,231, filed on Jan. 31, 2008.

### BACKGROUND

This invention relates generally to phase change memories.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

FIG. 1 is a partial, enlarged, perspective view of one embodiment at an early stage;

FIG. 2 is a partial, enlarged, perspective view of the embodiment shown in FIG. 1 at a subsequent stage;

FIG. 3 is a partial, enlarged, perspective view of the embodiment shown in FIG. 2 at a subsequent stage;

FIG. 4 is a partial, enlarged, perspective view of the embodiment shown in FIG. 3 at a subsequent stage;

FIG. 5 is a partial, enlarged, perspective view of the embodiment shown in FIG. 4 at a subsequent stage; and

FIG. 6 is a system depiction in accordance with one embodiment.

### DETAILED DESCRIPTION

In accordance with some embodiments, a phase change memory may have a self-aligned top electrode. The techniques used to form the memory may be compatible with pitch doubling and single damascene and copper electroplated metallization techniques in some embodiments.

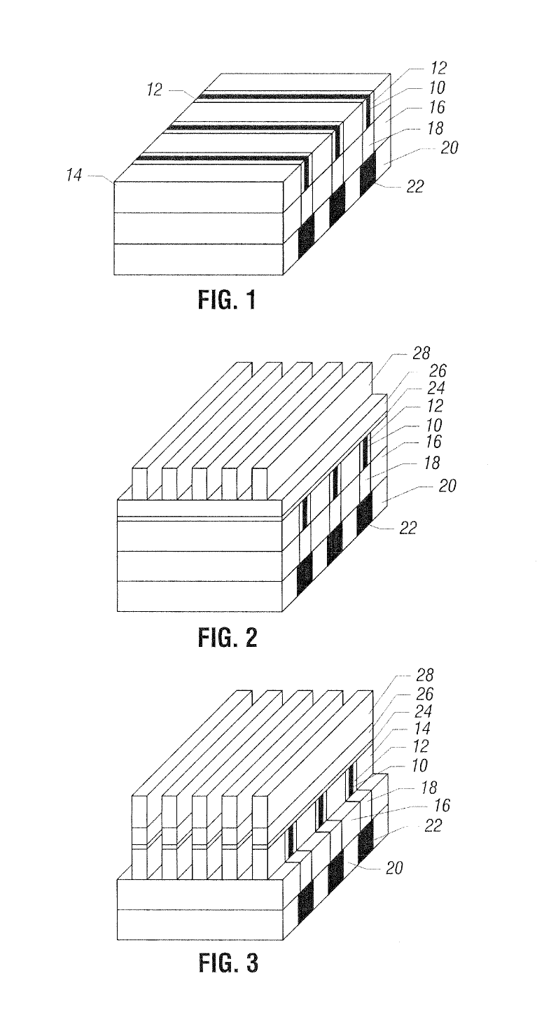

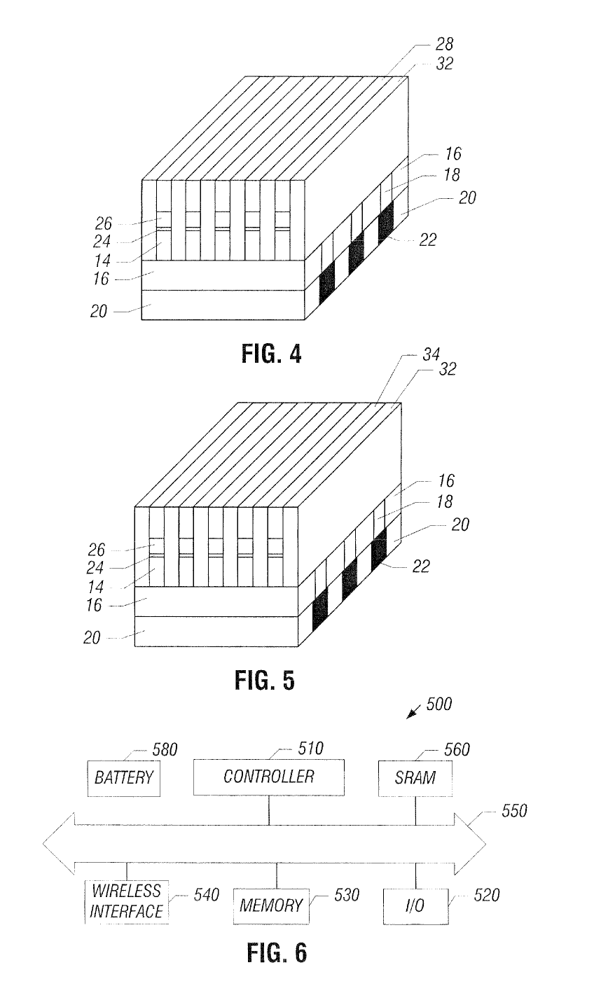

Referring to FIG. 1, over a semiconductor substrate (not shown) that may include other integrated components, may be formed a dielectric layer 20 that may be an interlevel dielectric (ILD) layer. Formed within the dielectric layer 20, using a damascene technique for example, may be metallization lines 22. In one embodiment, the lines 22 may be copper row lines.

A dielectric layer 16 may be formed thereover. Within the dielectric layer 16, in some embodiments, may be formed heaters 18, again using damascene techniques, for example. In one embodiment, the heaters 18 may be titanium silicon nitride.

Next, the memory elements 10 may be formed. The memory elements 10 may be formed on the sides of elongate spaced, parallel dielectric strips 14 that extend parallel to the lines 22. A first sidewall spacer layer 12 may be blanket deposited over the strips 14, and then anisotropically etched using a conventional sidewall spacer technique. Then, a second spacer layer (which is a chalcogenide) may be blanket deposited that includes a chalcogenide. A third spacer layer may be blanket deposited thereafter. Then, the second and third layers may be subjected to anisotropic etching, in one embodiment to form two sidewall spacers in one etching step.

In some embodiments, the upper and lower contact edges of the material 10 may be sub-lithographic since those edges were defined by the thickness of a blanket deposition, as opposed to being defined by lithography.

Alternatively, the second spacer or chalcogenide layer may be anisotropically etched and then the third spacer layer 12 may be formed thereover. As a result, a sandwich of sidewall spacers, including an inner dielectric sidewall spacer 12, an intermediate memory element 10, and an outer dielectric sidewall spacer 12 may be formed.

Then, the resulting structure may be coated with an ovonic threshold switch stack 24, a top electrode 26, and sacrificial material. The sacrificial material may be patterned as elongate, parallel, spaced strips 28, extending generally in a direction (e.g., a column direction) perpendicular to the direction of the metal lines 22.

The ovonic threshold switch stack 24 may include successive layers, from bottom to top, of a middle electrode, an amorphous chalcogenide, and a top electrode.

Sacrificial layer patterning can use direct patterning or pitch doubled patterning techniques. A sacrificial material can be deployed that has high etch selectivity to the underlying and surrounding material.

Referring to FIG. 3, using the strips 28 as a mask, the structure is etched down to the layer including the heater 18 and dielectric 16. Thus, either the heater 18 or the dielectric layer 16, or both, may act as an etch stop to the etching. In one embodiment, the strips 28 may be formed of a polysilicon material which may be selectively etched relative to one or the other of the heater 18 or dielectric 16.

As a result of the patterning shown in FIG. 3, the memory elements 10 are segmented into a series of discrete, spaced, segmented portions in the row direction having one portion for each column electrodes 26. Therefore, the memory elements 10 are self-aligned to the eventual column electrodes 26 that extend in a direction transverse to the lines 22, because of the etching using the strips 28 as a mask. The sequence shown in FIGS. 2 and 3 can be combined, in some cases, with masked direct patterning techniques.

Then, a gap fill technique is utilized to fill in the gaps between the adjacent strips 28 and the resulting structure planarized using chemical mechanical planarization, stopping on the layer including the strips 28.

Next, as shown in FIG. 5, the sacrificial layer including strips 28 is removed and metal is electroplated in place of the strips 28 to form the metal lines 34. The line 34 may be copper column lines in one embodiment. The resulting structure is again chemical mechanical planarized, stopping on the gap fill material 32 in one embodiment. Each of the segmented phase change material portions 10 extend in a direction perpendicular to the length of the metal lines 34.

Programming to alter the state or phase of the material may he accomplished by applying voltage potentials to the lines 34 and lines 22, thereby generating a voltage potential across a memory element including a phase change material 10. When the voltage potential is greater than the threshold voltages of any select device and memory element, then an electrical current may flow through the phase change material 10 in response to the applied voltage potentials, and may result in heating of the phase change material 10.

This heating may alter the memory state or phase of the material 10, in one embodiment. Altering the phase or state of the material 10 may alter the electrical characteristic of memory material, e.g., the resistance of the material may be altered by altering the phase of the memory material. Memory material may also be referred to as a programmable resistive material.

In the “reset” state, memory material may be in an amorphous or semi-amorphous state and in the “set” state, memory material may be in an a crystalline or semi-crystalline state. The resistance of memory material in the amorphous or semi-amorphous state may be greater than the resistance of memory material in the crystalline or semi-crystalline state. It is to be appreciated that the association of reset and set with amorphous and crystalline states, respectively, is a convention and that at least an opposite convention may be adopted.

Using electrical current, memory material may be heated to a relatively higher temperature to amorphosize memory material and “reset” memory material (e.g., program memory material to a logic “0” value). Heating the volume of memory material to a relatively lower crystallization temperature may crystallize memory material and “set” memory material (e.g., program memory material to a logic “1” value). Various resistances of memory material may be achieved to store information by varying the amount of current flow and duration through the volume of memory material.

One or more MOS or bipolar transistors or one or more diodes (either MOS or bipolar) may be used as the select device. If a diode is used, the bit may be selected by lowering the row line from a higher deselect level. As a further non-limiting example, if an n-channel MOS transistor is used as a select device with its source, for example, at ground, the row line may be raised to select the memory element connected between the drain of the MOS transistor and the column line. When a single MOS or single bipolar transistor is used as the select device, a control voltage level may be used on a “row line” to turn the select device on and off to access the memory element.

Turning to FIG. 6, a portion of a system 500 in accordance with an embodiment of the present invention is described. System 500 may be used in wireless devices such as, for example, a personal digital assistant (PDA), laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may he used to store user data. Memory 530 may be provided by one or more different types of memory. For example, memory 530 may comprise any type of random access memory, a volatile memory, a non-volatile memory such as a flash memory and/or a memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

References throughout this specification to “one embodiment” or “an embodiment” mean that a particular feature, structure, or characteristic described in connection with the embodiment is included in at least one implementation encompassed within. the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
blanket depositing electrode material over spaced, parallel, first strips of phase change material extending in a first direction; and
patterning the electrode material in a direction perpendicular to said first direction so as to segment the first strips of phase change material into individual portions, self-aligned to each top electrode.

2. The method of claim 1 wherein said strips of phase change material include an elongate structure having at least one sidewall spacer formed of phase change material.

3. The method of claim 1 wherein blanket depositing electrode material includes forming a plurality of spaced, parallel, elongate masks, and forming sidewall spacers on the sides of said mask.

4. The method of claim 3 including forming a phase change material sidewall spacer on both sides of a parallel, elongate mask.

5. The method of claim 4 including forming a sidewall spacer between an elongate mask. and said phase change material sidewall spacer,

6. The method of claim 5 including forming a sidewall spacer on the outside of each of said phase change material sidewall spacers.

7. The method of claim 1 wherein patterning said electrode material includes forming a series of spaced, parallel, elongate second strips extending generally perpendicular to said first strips.

8. The method of claim 7 including forming a heater under said first strips of phase change material.

9. The method of claim 8 including patterning down to, but not through, said heater.

10. The method of claim 9 including filling trenches, formed by patterning, with a filler material.

11. The method of claim 10 including removing said filler material and forming a metal in place of said filler material.
